(19) United States
(12) Patent Application Publication
(10) Pub. No.: US 2026/0194819 A1
(43) Pub. Date: Jul. 9, 2026

(54) CONTAMINATION CONTROL

(71) Applicant: ASML Netherlands B.V., Veldhoven (NL)

(72) Inventors: Andrey NIKIPELOV, Eindhoven (NL); Marcus Adrianus VAN DE KERKHOF, Helmond (NL); Elmar Leon GOOL, Eindhoven (NL); Vladimir KVON, Eindhoven (NL); Christian Gerardus Norbertus Hendricus Marie CLOIN, Eindhoven (NL); Tahmid HOSSAIN, Helmond (NL)

(73) Assignee: ASML Netherlands B.V., Veldhoven (NL)

(21) Appl. No.: 19/133,067

(22) PCT Filed: Oct. 27, 2023
(86) PCT No.: PCT/EP2023/080091

§ 371 Date: May 27, 2025

(30) Foreign Application Priority Data
Dec. 9, 2022 (EP) 22212483.6

(51) Int. Cl. G03F 7/00

(52) U.S. Cl. CPC G03F 7/70033; G03F 7/70916

(57) ABSTRACT

A lithographic patterning device contamination control system comprising a support structure configured to support a patterning device, and an electron beam source configured to emit a beam of electrons such that at least part of the beam is incident on a patterned face of a patterning device supported by the support structure during EUV exposure.

### CROSS-REFERENCE TO RELATED APPLICATIONS

This application claims priority of EP Application Serial No. 22212483.6 which was filed on 9 Dec. 2022, and which is incorporated herein in its entirety by reference.

### FIELD

The present invention relates to contamination control in a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a deep ultraviolet (DUV) wavelength of 193 nm.

In a conventional (DUV) lithographic apparatus, a pellicle is attached to the patterning device. The pellicle is a membrane which is spatially separated from the patterning device. A contamination particle which is incident upon the pellicle will be out of focus when projected by the lithographic apparatus onto a substrate. As a result, the contamination particle does not introduce a defect into a pattern projected by the lithographic apparatus from the patterning device onto the substrate.

A pellicle may also be used in an EUV lithographic apparatus. However, EUV radiation is absorbed by the pellicle, and this reduces the intensity of EUV radiation which may be used to expose a substrate. This in turn reduces the throughput of the lithographic apparatus. Maintaining patterning device cleanliness during EUV exposure can be achieved by suppression of contamination particle release and/or transport from contaminated surfaces near the patterning device. This is an alternative to the use of pellicles. However, some contamination particles may continue to be incident upon the patterning device.

It may be desirable to provide an apparatus that overcomes or mitigates one or more problems associated with the prior art.

### SUMMARY

According to a first aspect of the present invention, there is provided a lithographic patterning device contamination control system comprising a support structure configured to support a patterning device, and an electron beam source configured to emit a beam of electrons such that at least part of the beam is incident on a patterned face of a patterning device supported by the support structure during EUV exposure.

Advantageously, the electron beam provides contactless control of the potential of the patterned face of the patterning device (i.e. does not require a physical wire contact, that may generate contaminants or damage critical surfaces of the patterning device). The electron beam may keep a time-averaged potential of the patterning device MA at a negative voltage (e.g. −0.1 V . . . −10 V), or can prevent a positive time-averaged potential of the patterning device MA (e.g. that reaches +1 V . . . +5V). A negative potential of the patterning device will create a favourable electric field which repels contamination particles from the patterning device.

A line of sight may extend from the electron beam source to the patterning device.

The line of sight may extend from the electron beam source to the patterning device may exist for all positions of the patterning device during EUV exposure.

The electron beam source may be configured to emit electrons with an energy of at least 1 eV.

The electron beam source may be configured to emit electrons with an energy of up to 13.5 eV.

The electron beam source may be configured to emit electrons with an energy of up to 100 eV.

The electron beam source may be located at a distance of more than 10 cm the patterning device and wherein the electron beam source is configured to emit electrons with an energy of at least 10 eV.

The electron beam source may be located at a distance of 10 cm or less from the patterning device.

The electron beam source may be located at a bottom of a housing which defines a patterning device environment. The electron beam source may be located adjacent to a wall of an opening provided in the housing.

The electron beam source may be configured to emit electrons with a current of at least 100 μA.

The electron beam source may be configured to emit electrons with a current of up to 100 mA.

The electron beam source may be configured to output an electron beam with an elliptical cross-sectional shape. The elliptical beam may have an aspect ratio of more than one, preferably more than two, and most preferably more than three.

The electron beam source plasma electrode may be in contact with one of: stainless steel, tungsten, molybdenum, tantalum metals or alloys, that are resistant to sputtering by hydrogen or helium ions with energy up to 100 eV.

The electron beam source may comprise at least one permanent magnet and magnetic shielding material, such as mu-metal.

The electron beam source may have a housing which is grounded and is in electrical contact with a frame of the lithographic tool.

The electron beam source housing may be made in one of: stainless steel, tungsten, molybdenum, tantalum metals or alloys, that are resistant to sputtering by hydrogen EUV plasma.

The electron beam source may be connected to an RF power supply configured to provide power with a frequency in the range 0.1 GHz to 10 GHz. The frequency may preferably be in the range 1 GHz to 3 GHz. The electron beam source may be connected to a DC power supply configured to provide up to 100 mA. The electron beam source may be connected to a DC power supply configured to provide and up to −1 kV (to support electron beam extraction), or up to +1 kV (to support extraction of a beam of positively charged ions).

The electron beam source may be connected to a supply of at least one of H₂ and He.

The electron beam source may be configured to direct the electron beam to an exposure zone within a patterning device environment.

The electron beam source may be configured to direct the electron beam to a location which is offset from the exposure zone.

An additional electron beam source may be configured to direct an additional electron beam to a location which is offset in an opposite direction relative to the exposure zone.

The electron beam source may be one of a plurality of electron beam sources.

The electron beam source may be configured to maintain the patterning device at a negative potential at least on a time-averaged basis during EUV exposure.

The electron beam source may further comprise a controller configured to switch a polarity applied to the electron beam source such that the electron beam source outputs positive ions.

According to a second aspect of the invention there is provided a lithographic apparatus comprising the patterning device contamination control system of any preceding claim, and further comprising masking blades, a patterning device exchange system, and a housing within which a patterning device environment is located.

The electron beam source may be provided in a wall which defines an opening that leads to the patterning device environment.

The electron beam source may be located at a height which corresponds with a height of the masking blades. The electron beam source may be offset in a direction which is orthogonal to a scanning direction of the patterning device support structure.

The electron beam source may be located adjacent to a patterning device exchange system.

According to a third aspect of the invention there is provided a lithographic apparatus comprising a source of electrons and an ionizer located in a patterning device environment.

The source of electrons and ionizer may advantageously create a plasma which neutralizes charge on a back side of the patterning device during manipulation of the patterning device.

The lithographic apparatus may further comprise a controller configured to activate the ionizer when the lithographic apparatus is not performing a lithographic exposure.

According to a fourth aspect of the invention there is provided a method of controlling contamination of a lithographic patterning device, the method comprising directing an electron beam to a patterned face of the patterning device.

The electron beam provides contactless control of the potential of the patterned face of the patterning device (i.e. does not require a physical wire contact, that may generate contaminants or damage critical surfaces of the patterning device).

Gas may be supplied to the plasma electrode of the electron beam source, the gas comprising at least one of H₂ and He

The electron beam may maintain the patterning device at a negative potential on a time-averaged basis during EUV exposure.

According to a fifth aspect of the invention there is provided a method of controlling charge on a back surface of a lithographic patterning device, the method comprising directing a beam of electrons or a beam of positive ions towards a back surface of the lithographic patterning device when it is manipulated by a patterning device exchange system.

Advantageously this may prevent high voltages and consequent discharge occurring when the patterning device is manipulated.

Features of different aspects of the invention may be combined together.

### BRIEF DESCRIPTION OF THE DRAWINGS

Embodiments of the invention will now be described, by way of example only, with reference to the accompanying schematic drawings, in which:

FIG. 1 schematically depicts a lithographic system which includes a patterning device contamination control system according to an embodiment of the invention;

FIG. 2 schematically depicts the contamination control system in more detail;

FIG. 3 schematically depicts an electron emitter which forms part of the contamination control system;

FIG. 4 schematically depicts a patterning device contamination control system according to an alternative embodiment; and

FIG. 5 schematically depicts a patterning device contamination control system according to a further alternative embodiment.

### DETAILED DESCRIPTION

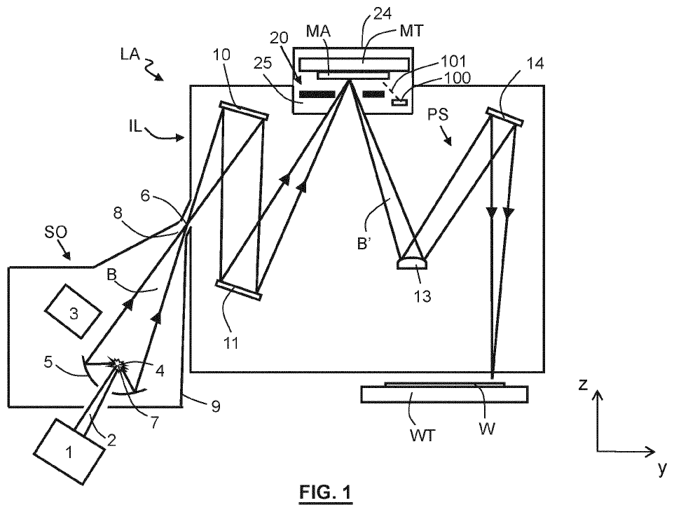

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The support structure MT may comprise a clamp that is used to hold the patterning device MA. The clamp may be an electrostatic clamp that is electrically driven. There may be a dielectric layer between the clamp and the patterning device MA. At least part of the support structure MT may be at electrical ground.

The patterning device MA and other elements may be provided within a housing 24. An interior defined by the housing may be referred to as a patterning device environment 25. The housing 24 may be substantially closed, apart from an opening at a bottom end of the housing. A set of masking blades 20 is provided in the patterning device environment 25. The masking blades are 20 is used to selectively mask areas of the patterning device MA, such that only a desired portion of the patterning device receives EUV radiation at any given time. During a scanning exposure, the patterning device MA and support structure MT move in the y-direction, and the substrate W and substrate table WT move in the opposite y-direction (and vice-versa). In this way, a band of EUV radiation passes over the patterning device MA and passes over an exposure field on the substrate W.

An electron beam source 100 is provided in the patterning device environment 25. The electron beam source 100 in FIG. 1 is below and to one side of a blade of the reticle masking blade system 20. However, the electron beam source 100 may be provided at a different location, e.g. somewhere else within the patterning device environment 25. An electron beam 101 provided by the electron beam source, in combination with EUV (photo-effect) and EUV plasma (charging by ion and electron current), together determine both an instantaneous and an average potential of the patterned surface of the patterning device MA (the patterned surface is conducting). The electron beam 101 is illustrated as a line, but in practice may diverge and does not necessarily travel in a straight line. Electrons output from the electron source 100 are scattered by gas molecules, ions and other electrons. In addition, the electrons experience electrostatic forces due to electrical charges on surfaces in the patterning device environment 25. The electrons are accelerated by those forces.

A relative vacuum, i.e. a small amount of gas (e.g. hydrogen) at a pressure well below atmospheric pressure, may be provided in the radiation source SO, in the illumination system IL, and/or in the projection system PS. The same is also the case for the patterning device environment 25. That is, gas at a pressure below atmospheric pressure is present in the patterning device environment 25. The gas may for example be hydrogen. The gas may be partially ionized by EUV radiation B and/or by the electron beam 101.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

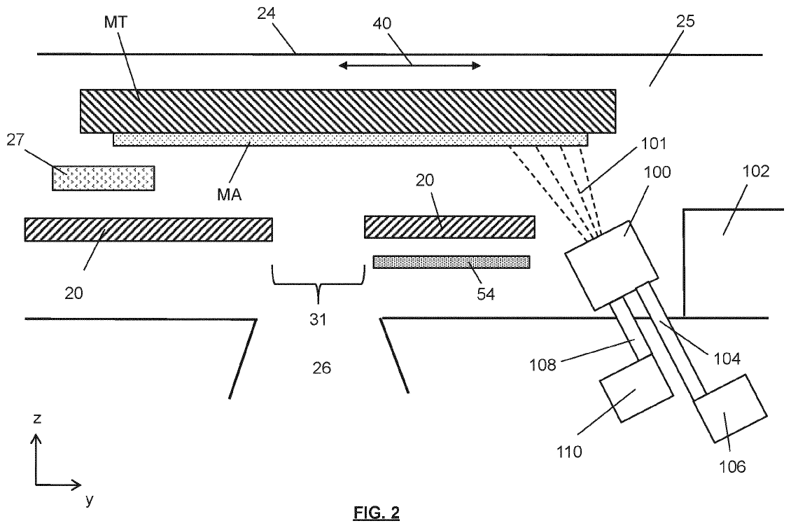

FIG. 2 schematically depicts part of the lithographic apparatus LA in more detail. Specifically, FIG. 2 schematically depicts the patterning device MA, support structure MT, masking blades 20, electron-beam source 100 and other elements which are provided in the housing 24. An opening 26 is provided at a lowermost end of the housing 24. The EUV radiation beam enters the housing 24 through this opening, is reflected from the patterning device MA and then exits through the same opening 26. The masking blades 20 define an exposure zone 31 through which the EUV radiation passes before being incident upon the patterning device MA. The exposure zone 31 may be considered to be a volume having sides defined by the masking blades 20, the volume extending up to the patterning device MA. An area of the patterning device MA which receives the EU radiation may be referred to as an exposure area.

A gas supply system 27 is provided in the housing 24. The gas supply system 27 is on one side of the exposure zone 31, and provides a flow of gas across the exposure zone. A gas removal system (not depicted) may be provided to remove gas from an opposite side of the exposure zone 31. A beam attenuator 54, which is moveable in the Y-direction (the scanning direction of the lithographic apparatus) is provided in the housing 24. The beam attenuator 54 may for example comprise a series of fingers which may be moved into partial intersection with the EUV radiation beam, thereby providing some attenuation of radiation beam when desired.

A patterning device exchange system 102 connects to the housing 24. Only part of the patterning device exchange system 102 is visible in FIG. 2. The patterning device exchange system 102 is configured to receive a patterning device MA from the support structure MT such that the patterning device may be removed from the patterning device environment 25. The patterning device exchange system 102 is further configured to deliver a different patterning device MA to the support structure MT in order to allow a different pattern to be projected onto substrates W by the lithographic apparatus LA (see FIG. 1).

The electron beam source 100 is connected via an electrical connection 104 to a current and voltage source 106. The electron beam source 100 is connected via a conduit 108 to a gas source 110. The electrical connection 104 and the gas conduit 108 may pass through a wall of the housing 24. The electron beam source 100 may be secured to the housing 24. The electron beam source 100 may be located adjacent to the patterning device exchange system 102 (as schematically depicted) or at a different location. The current and voltage source 106 may be configured to provide DC and/or AC power. The electron beam source 100 may emit electrons via field emission or thermal emission, or may extract electrons from a dedicated plasma source. The current and voltage source 106 may power electron emission or maintain a dedicated plasma. The current and voltage source 106 may also accelerate emitted or extracted electrons to a desired energy. The gas source 110 may be configured to maintain a desired pressure within the electron source 100, that for example is higher than a nominal pressure in the environment 25. Providing pressure within the electron source that is higher than the nominal pressure may help to maintain a dedicated plasma.

The gas source 110 may for example provide Hydrogen gas or Helium gas. Hydrogen and Helium are preferred over other gases, because other gases may cause sputtering by heavy collateral ions, which will contaminate optics of the lithographic apparatus and reduce EUV transmission of the optics.

The electron beam 101 extends from the electron beam source 100 to a patterned face of the patterning device MA. A line of sight extends from the electron beam source 100 to the patterning device MA. The electron beam 101 is schematically illustrated as diverging as it travels towards the patterning device MA. In practice, the electron beam may diverge more than is schematically depicted. The divergence may be non-uniform.

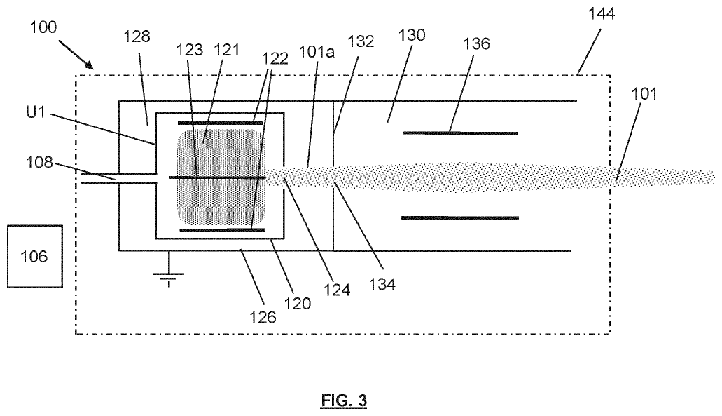

An example of the electron beam source 100 is schematically depicted in FIG. 3. This example depicts an electron source in which electrons are extracted from plasma, in particular an RF-plasma with an optional magnetic confinement (ECR-plasma). Other plasma source as well as thermal and field emission may act as sources of electrons. The electron beam source comprises a chamber 120 to which gas 121, for example hydrogen is delivered via the conduit 108. An RF antenna 123 within the chamber 120 receives an RF electrical signal. An electric field established by the RF antenna 123 ionizes the gas 121, thereby generating a plasma 121 (the same reference numeral is used for the gas and the plasma since both are in the same location). Electrodes 122 are located adjacent to walls of the chamber. A negative DC voltage is provided to the electrodes 122. This pushes electrons out of the chamber 120 through an opening 124. Walls of the chamber 120, which may be referred to as a plasma chamber for ease of identification, have the same negative DC voltage as the electrodes 122 (due to conduction by the plasma between the electrodes 122 and walls of the plasma chamber 120). A permanent magnet (not depicted) may be used confine electrons close to the electrodes 122. In some embodiments the electrodes 122 may be omitted. In such embodiments, a negative voltage may be provided directly to walls of the plasma chamber 120.

As explained above, the plasma chamber 120 is biased with a negative voltage. The plasma chamber 120 is provided within a housing 126 which is connected to ground. The ground may be a frame of the lithographic apparatus. The housing 126 comprises a first chamber 128 and a second chamber 130. The first and second chambers, 128, 130 are separated by a dividing wall 132 which is provided with an opening 134. Electrons 101a which pass out of the first opening 124 are accelerated by the negative voltage at the walls of the plasma chamber 120 (and electrodes 122 when these are present) and pass through the opening 134 in the dividing grounded wall 132 and form an electron beam.

An Einzel lens 136 is provided in the second chamber 130. The Einzel lens 136, which is optional, refocuses the electron beam such that it forms an electron beam 101. When electron beam is positioned sufficiently close to the patterning device MA, for example closer than 10 cm, the Einzel lens focusing is unnecessary and it may be omitted.

The housing 126, the housing of the plasma chamber 120, the electrodes 122, and RF antenna 123 are used to ignite and maintain ECR discharge (not depicted) may be formed from the same material. These parts, and in general any metal that comes in contact with the plasma 121 or electron beam 101, may be formed from stainless steel, tungsten, molybdenum, tantalum metals or alloys, that are resistant to sputtering by hydrogen or helium plasma with ion energy of less than 100 eV, or by EUV hydrogen plasma

The above features, such as grounding of the plasma chamber 120, or the material of the housing 126 or other part, may apply for other electron sources (e.g. electron sources which have a different configuration to the electron source depicted in FIG. 3).

The electron beam source 100 may be for example a mini-ECR based source from Polygon Physics of Meylan, France.

The ECR-based electron beam source 100 has a significant magnetic field. It may be undesirable for this magnetic field to extend within the patterning device environment 25 because it can disturb scanning movement of the patterning device. For this reason, the electron beam source 100 may be enclosed in a Mu-metal box 144 (or other magnetic shield). The Mu-metal box 144 includes an opening out of which the electron beam 101 may pass. (Mu-metal is a nickel-iron soft thermomagnetic alloy). Mu-metal is advantageous for shielding the patterning device environment 25 from the magnetic field because it has a high permeability. Other high permeability material may be used. If Mu-metal is used then a coating may be provided on the Mu-metal. The coating may be configured to prevent interaction between hydrogen plasma in the patterning device environment 25 and the Mu-metal (this may cause undesirable fragmentation or cracking or hydrogen embrittlement). Examples of suitable coatings are NiP (nickel-phosphorus), Cr, Mo, other refractory or noble metals. The coating may have a preferred thickness of 0.5-5 μm. Instead of a coating, an additional box (not depicted) may be provided around the Mu-metal box 144. The additional box may be formed from a metal such as steel which does not react with hydrogen plasma. Another additional box may be provided inside the Mu-metal box 144. This additional box may also be formed from a metal such as steel which does not react with hydrogen plasma.

As schematically depicted in FIGS. 1 and 2, the electron beam 101 extends from the electron beam source 100 to the patterning device MA. The electron beam 101 provides contactless control of the potential of the patterned face of the patterning device MA (i.e. does not require a physical wire contact, that may generate contaminants or damage critical surfaces of the patterning device MA). The electron beam 101 may keep a time-averaged potential of the patterning device MA at a negative voltage (e.g. −0.1 V . . . −10 V) or can prevent a positive time-averaged potential of the patterning device MA (e.g. that reaches +1 V . . . +5V). A negative potential of the patterning device MA, in combination with grounded masking blades 20, grounded gas delivery system 27 and grounded beam attenuator 54 will create a favourable electric field which repels contamination particles from the patterning device MA. Most contamination particles are negatively charged due to the effect of EUV-induced plasma in the low pressure hydrogen in the environment 25 and/or photo-electrons output from the patterned device due to EUV photon irradiation. The negatively charged patterning device MA thus repels negatively charged contamination particles.

Although the electron beam 101 is incident at one end of the patterning device MA, a patterned face of the patterning device is conductive and thus the negative potential is distributed over the patterning device.

If the electron beam source 100 were not present then the patterned face of the patterning device MA would be positively charged and would attract negatively charged contamination particles. The positive charge, which could be around 3V, arises from a combination of effects, being photo-emission of electrons from the patterning device MA caused by EUV, and interaction of EUV induced plasma in the vicinity of the patterned face of the patterning device MA. The positively charged patterning device face, in combination with the grounded masking blades 20 and other grounded components, attracts negatively charged contamination particles towards the patterning device. This undesirable situation is avoided by embodiments of the invention.

The current of the emitted electron beam may be sufficient to provide a current of at least 100 μA at the patterned surface of the patterning device MA. In order to provide a current of at least 100 μA at the patterned surface of the patterning device MA, the electron beam source 100 may be configured to output an electron beam 101 having a significantly higher current than 100 μA. For example, the electron beam source 100 may output an electron beam having a current of at least 1 mA. The electron beam source 100 may output an electron beam having a current of for example up to 10 mA. The current may be sufficient to keep the voltage at the patterning device face at a negative potential (e.g. around −0.1V to −10V instead of around +1 to +5V on a time averaged basis). The current may be sufficient to remove the positive voltage of the patterning device in less than 10 μs after each EUV pulse, and thus is faster than a 20 us gap between EUV pulses provided by the source SO. This ensures that a time-averaged potential of the patterning device remains negative.

The current of the electron beam 101, and the voltage of the patterning device, may be such that they do not generate significant heat. The power absorbed by the patterning device from the electron beam 101 may for example be less than 10% of the power absorbed from the EUV beam B. The power absorbed by the patterning device from the electron beam 101 may for example be 1 W or less.

As depicted by arrow 40 in FIG. 2, the patterning device MA moves back and forth in the Y-direction during scanning exposures. Thus, a dynamic system is established in which the patterning device MA moves through the EUV beam B, with the EUV beam B continuously causing the patterning device to be positively charged. The current of the electron beam 101 should be sufficient to counteract the photo-effect of the EUV beam B such that the patterning device face remains at a negative potential at every position within a range of scanning movement of the patterning device.

The energy of electrons in the electron beam 101 may be e.g. at least 1 eV. It may be desirable for the electrons to have an energy of at least 1 eV because this will help to minimise electron attachment ionization.

The electron beam source 100 may be located for example within 10 cm from the patterning device MA (e.g. when scanning movement of the patterning device has moved the patterning device such that it is above the electron beam source). The energy of the electrons in the electron beam may be up to 13.5 eV. This is desirable because that energy is below the hydrogen ionization potential (13.6 eV), and thus the electrons do not ionize hydrogen atoms via electron impact in the patterning device environment 25. Hydrogen ions are not desirable because they may promote particle release from the contaminated surfaces near the patterning device MA. Although it is preferred that the energy of the electrons in the electron beam is up to 13.5 eV, the energy of the electrons may be greater than this (although some ionization of hydrogen atoms may then be caused). The electrons may for example have an energy of up to 100 eV. Having electrons with an energy greater than 100 eV may be undesirable because at such high energies secondary electron yield will increase to be greater than 1, and the secondary electron yield will reduce negative charge provided by the electron beam to the patterning device.

If the electron beam source 100 is more than e.g. 10 cm away from the patterning device, then the electrons in the electron beam 101 may be provided with an energy of e.g. at least 10 eV, so that they have sufficient energy to travel to the patterning device. If the electrons were to have a lower energy then they might be attenuated or dissipate in hydrogen in the patterning device environment 25 before they reach the patterning device. The electrons may for example have an energy of more than 13.5 eV. The electrons may for example have an energy of up to 100 eV. As explained above, providing the electrons with an energy greater than 100 eV may be undesirable.

The electron beam source 100 may have a line of sight to the patterning device MA (e.g. as shown in FIG. 2). Where this is the case, the electron beam 101 may extend in a straight line to the patterning device MA. In other embodiments, the electron beam 101 may have no line of sight to the patterning device MA. Where this is the case, some electrons will travel in a curve to the patterning device. The EUV beam causes a positive potential of the patterning device, and as a result the electrons may be attracted to the patterning device (and thus may curve towards the patterning device). Alternatively at least part of the electron beam can reach the patterning device due to scattering of gas molecules, ions, other electrons and due to interaction with volume or surface charges.

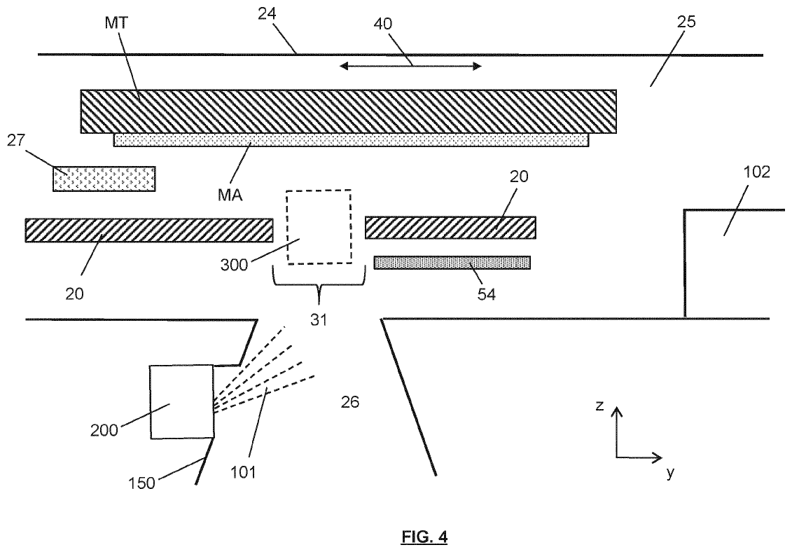

An embodiment of the invention is depicted in FIG. 4. In this embodiment, the electron beam source 200 is recessed into a wall 150 of the opening 26 that leads to patterning device environment 25. In the depicted embodiment, the electron beam 101 is directed generally upward and towards the patterning device MA. The electron beam source 100 may have a line of sight to the patterning device MA. The electron beam may be incident upon the patterning device MA in the exposure zone 31. An advantage of this arrangement is that the patterning device MA does not move towards and away from the electron beam source 200, and thus the current provided to the patterning device by the electron beam may stay generally constant. Alternatively the electron beam 101 may be directed towards the EUV beam B but not towards the EUV illuminated region of the patterning device MA.

In the embodiment depicted in FIG. 4, electrons of the electron beam 101 may have an energy of more than 10 eV (e.g. up to 100 eV). If the electrons were to have a lower energy then they would be likely to be attenuated before reaching the patterning device (lower energy electrons tend to diverge from the electron beam more than higher energy electrons and therefore dissipate more quickly). The electrons lose energy as they travel to the patterning device, and as a result may have an energy of less than 10 eV (on average) when they are incident on the patterning device. The electrons may similarly have an energy of less than 10 eV when incident upon other surfaces in the vicinity of the patterning device.

Directing the electron beam 101 towards the exposure zone 31 is advantageous, because plasma generated by EUV radiation in the exposure zone will attract electrons of the electron beam and guide the electrons towards the patterning device MA. The electron beam 101 may have a cross sectional size which generally corresponds with, or is generally smaller than, an opening defined by the masking blades 20. This advantageously avoids or reduces electron beam loses due to electrons being incident upon the masking blades.

In a further alternative embodiment, the electron beam source 300 may be located at approximately same height (i.e. z-direction position) as the masking blades 20. The electron beam source 300 may be positioned to one side of the masking blades 20 (i.e. offset in the X-direction). In such a configuration, the electron beam source 300 may have no line of sight to the patterning device MA. The electron beam may curve towards the patterning device MA. An advantage of this arrangement is that the patterning device MA does not move towards and away from the electron beam source 300, and thus the current provided to the patterning device by the electron beam may stay generally constant. A single electron beam source may be provided when this arrangement is used.

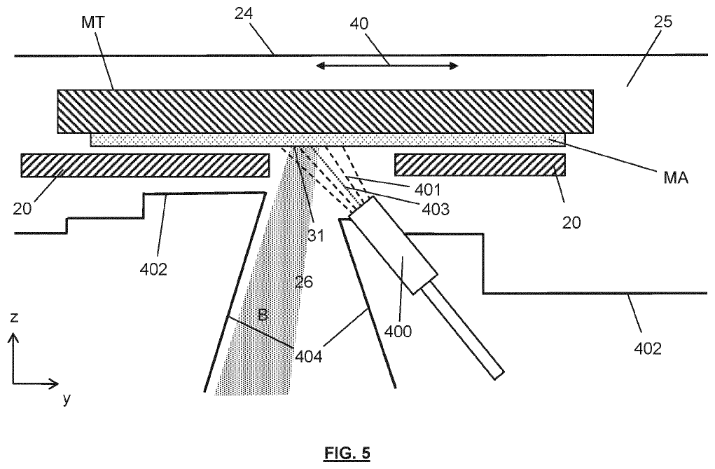

A further alternative embodiment of the invention is depicted in FIG. 5. In this further embodiment, the patterning device MA, support structure NT, and masking blades 20 are as described further above in connection with other embodiments. The gas supply system, beam attenuator, and patterning device exchange system are omitted from FIG. 5 for ease of illustration. The depicted height of the patterning device environment 25 is reduced compared with the depiction in other figures of this application, such that relative positions of apparatus elements depicted in FIG. 5 more closely resemble a physical lithographic apparatus (although FIG. 5 remains schematic).

The beam of EUV radiation B is depicted, unlike in other embodiments. The exposure zone 31 may be seen in FIG. 5. The exposure zone 31 is the location at which the EUV beam B intersects with the patterning device MA in use.

A bottom of the housing 24 which contains the patterning device environment 25 comprises a floor which may be made up of upper surfaces of different apparatus elements. This is schematically depicted in FIG. 5 as a stepped floor 402. An opening 26 is provided in the stepped floor 402 of the housing 24. The opening comprises a pair of walls 404. The walls 404 are angled to form an inwardly tapering space through which the EUV radiation beam B may pass, and through which reflected EUV radiation (not depicted) may also pass.

An electron beam source 400 is provided to one side of the opening 26 (in the scanning, y-direction). The electron beam source 400 may be located at the bottom of the housing 24. The electron beam source 400 may be located adjacent to one of the walls 404 of the opening 26. The electron beam source 400 may form part of a floor (e.g. stepped floor 402 formed from upper surfaces of apparatus elements) of the housing 24.

The electron beam source 400 emits an electron beam 401. The electron beam 401 is angled with respect to the vertical (z-direction), such that the electron beam points generally towards the exposure zone 31. This may be achieved by arranging the electron beam source 400 to be angled with respect to the vertical (as depicted), or by configuring the electron beam source to emit the electron beam at an angle (as explained further below). The electron beam 401 has some divergence such that the size of a cross-sectional area of the electron beam increases as a function of distance from the electron beam source 400. The electron beam 401 may extend fully across the exposure zone 31 in the scanning direction (y-direction) of the lithographic apparatus (as depicted). A middle of the electron beam 401, schematically depicted by a dotted line 403, may overlap with the exposure zone 31.

The electron beam 401 may be directly incident upon the patterning device MA in the exposure zone 31. This advantageously means that the patterning device MA does not move towards and away from the electron beam 401 in use. Instead, the electron beam 401 remains continuously incident upon the patterning device MA during a lithographic exposure. The current emitted to the patterning device MA by the electron beam source 401 may stay generally constant during a lithographic exposure, or can be modulated with the help of bias or RF power modulation. The constant current emitted by the electron beam source is more robust and reliable and it is a preferred embodiment.

A separation between the electron beam source 400 and the patterning device MA may be less than 10 cm. The separation may for example be less than 4 cm. The separation may for example be around 3 cm. Providing the electron source 400 at such a separation, which is relatively close to the patterning device MA, is advantageous because it allows electrons to be provided with an energy of less than 13.6 eV. The separation is sufficiently small that an energy of less than 13.6 eV is sufficient for a majority of the electrons to reach the patterning device MA. Advantageously, the electrons do not have sufficient energy to ionize hydrogen atoms via electron impact in the patterning device environment 25.

Although the separation is sufficiently small that a majority of electrons with an energy of less than 13.6 eV will reach the patterning device, electrons with a higher energy may be used. For example electrons with an energy of 30 eV or more may be used. Electrons with an energy of up to 100 eV may be used.

The electron beam source 400 may provide an electron beam current of at least 100 μA. The electron beam source 400 may provide an electron beam current of up to around 10 mA. This may also apply for other embodiments. These electron beam current values are a time averaged current for any embodiments in which the electron beam is modulated (the electron beam may be constant or modulated). A current of at least 100 μA may be sufficient to maintain a negative voltage at the patterning device MA. A current of more than 10 mA may be provided. However a current of up to 10 mA will fulfil the function of maintaining a negative voltage at the patterning device MA, and increasing the current beyond 10 mA will bring unnecessary stress (plasma created by the e-beam) to the environment.

In general, providing the electron beam source 400 at the bottom of the housing 24 and adjacent to a wall 404 of the opening 26 may advantageously provide a line of sight from the electron beam source to the exposure area 31, with a separation which allows electrons to have an energy about (for example) 10 eV, e.g. up to 100 eV, with the current of electron beam of (for example) up to 10 mA, while providing sufficient negative potential for the patterning device during exposure. Electron energy of more than 100 eV and/or electron beam current of more than 10 mA may be used, but these will bring unnecessary stress (plasma created by the e-beam) to the environment without providing a benefit.

A plurality of electron beam sources may be provided (for this embodiment or for other embodiments). The plurality of electron beam sources (not depicted) may be distributed in the x-direction such that electron beams 401 are incident at different x-direction positions on the patterning device MA. The electron beam sources 401 may for example have a separation which is sufficiently small that adjacent electron beams overlap with each other when they are incident upon the patterning device MA. A plurality of electron beam sources 400 may be distributed to provide overlapping electron beams such that a band of electrons stretches fully across the patterning device MA in the x-direction.

The electron beam source (for this embodiment or for other embodiments) may be configured to output an electron beam with an elliptical cross-sectional shape. For example, referring to FIG. 3, the Einzel lens 136 may have a rectangular cross-section (elongate in the x-direction), such that it provides the electron beam with an elliptical cross section. Other electrode configurations may be used. The elliptical beam may have an aspect ratio of more than one, preferably more than two, and most preferably more than three. An aspect ratio of more than three is most preferable because this spreads the electron beam across the patterning device MA in the x-direction by a greater degree (compared with an aspect ratio of less than three). This in turn may provide full coverage of the patterning device MA in the x-direction using fewer electron beam sources (for a given electron beam divergence and a given separation from the patterning device).

Over time, an electrode of an electron beam source of an embodiment of the invention (e.g. electrode 122 which provides RF excitation) may become damaged due to sputtering of hydrogen or helium ions (which may have an energy of up to 100 eV). To reduce the incidence of such damage, a gas may be supplied to the plasma electrode. The gas may be a single element or a mixture of elements. The gas may comprise at least one of H₂ and He.

To reduce damage of the electrode, the electrode may be in contact with one of: stainless steel, tungsten, molybdenum, tantalum metals or alloys, that are resistant to sputtering by hydrogen or helium ions with energy up to 100 eV.

The electron beam source may comprise at least one permanent magnet. The permanent magnet (not depicted) may be provided around the plasma chamber 120 and configured to confine electrons of the plasma 121. A magnetic shielding material such as Mu material may be located around the electron beam source, to shield the other parts of the lithographic apparatus from the magnetic field provided by the permanent magnet.

The lithographic patterning device contamination control system of any preceding claim, wherein the electron beam source outer wall is made in one of: stainless steel, tungsten, molybdenum, tantalum metals or alloys, that are resistant to sputtering by hydrogen EUV plasma.

The RF antenna 123 of the electron beam source may be connected to an RF power supply configured to provide power with a frequency in the range 0.1 GHz to 10 GHz. The frequency may preferably be in the range 1 GHz to 3 GHz. The RF antenna 123 may be connected to a DC power supply configured to provide up to 100 mA. Walls of the plasma chamber 120 (and electrodes 122 where these are present) may be connected to a DC power supply configured to provide and up to −1 kV (to support electron beam extraction, or up to +1 kV (to support extraction of a beam of positively charged ions).

In the embodiment depicted in FIG. 5 the electron beam 401 is generally symmetric about an axis which extends from the electron beam source 400 (i.e. the electron beam is not angled with respect to the electron beam source). However, in other embodiments (not depicted) the electron beam may be angled with respect to a body of the electron beam source. For example, the electron beam may have a tilt of up to 20°. The tilt of the electron beam can be arranged by offsetting the opening 134 in the dividing grounded wall 132 of the electron beam source (see FIG. 3) with respect to a central axis of the electron beam source (e.g. an axis defined by the RF antenna 123). Tilting of the electron beam may be aided by tilting the dividing grounded wall 132, and by tilting the plasma chamber wall in which the opening 124 is provided. Alternatively, an auxiliary electrode or magnet, can be placed near extraction grounded electrode opening 134 and can tilt the electron beam (101).

In general, the electron beam source may be provided at any location within the patterning device environment 25 or adjacent to the patterning device environment, such that the electron beam 101 can reach the patterning device MA. If the electron beam source is offset in the Y-direction (scanning direction) from the exposure zone 31, then the patterning device MA will move towards and away from the electron beam source, and thus the current provided to the patterning device by the electron beam will vary. The effectiveness of the electron beam current in maintaining a negative voltage at the patterning device face may correspondingly vary. To avoid this varying effectiveness, a first electron beam source may be offset in the Y direction from the exposure zone 31, and a second electron beam source may be offset in the −Y direction from the exposure zone 31. Alternatively, a single electron beam source may be provided, but with a higher output electron beam current (the current may be selected such that the patterning device face always has a negative voltage).

In an embodiment (not depicted) an electron beam source may be provided on either side of the exposure zone 31. Where this is done, the current provided to the patterning device may stay generally constant. However, such an embodiment may be more complex and expensive to implement than a single electron beam source embodiment.

During unloading of the patterning device MA from the support structure MT, it may be desirable to avoid a back side of the patterning device MA having a negative potential. Unloading (and loading) of the patterning device MA from (and to) the support structure MT by the patterning device exchange system 102 may be referred to as manipulating the patterning device. The patterning device MA may act as one plate of a capacitor, with the support structure MT acting as the other plate of the capacitor, and the capacitance of this capacitor will decrease rapidly as the patterning device is moved away from the support structure. If the back side of the patterning device is negatively charged, then the decreased capacitance will cause an increase of voltage. There is a risk that the voltage on the back side of the patterning device reaches kV levels, and may cause an electrical discharge. This is undesirable because it can damage the lithographic apparatus. Embodiments of the invention may neutralise or reduce a negative potential on the back side of the patterning device.

In an embodiment, a current of positive ions may be delivered to the back side of the patterning device MA. This current of positive ions may neutralise charge on the patterning device MA. The current of positive ions may be obtained by reversing a polarity applied to the electron beam source 100 (such that positively charged ions are delivered to vicinity of the reticle exchange device 102). Because the back side of the patterning device MA is negatively charged, it will attract the positive ions even if there is no line of sight to the back side of the patterning device. A controller may control the electron beam source such that positive ions are delivered when the lithographic apparatus is not performing a lithographic exposure, e.g. when the patterning device MA is being unloaded from the support structure. Alternatively, the electron beam source 100 operated in a normal electron emitting mode during patterning device load/unload can ionize hydrogen in the environment 25 and provide the necessary positive ions to the vicinity of the reticle exchange device 102.

In an embodiment, the electron beam source (or a different source of electrons) may be used to assist an ionizer in the generation of a plasma in the patterning device environment. The ionizer may for example be a coil which is configured to induce ionization of hydrogen gas in the patterning device environment. Electrons provided by the electron source may accelerate and thus help to ionize hydrogen molecules, thereby providing a ‘kick-start’ to ionization provided by the ionizer. Once an initial plasma has been generated, the plasma may become self-sustaining (provided that the ionizer continues to operate). The plasma will flow to the back side of the patterning device, and neutralise charge on the back side of the patterning device MA. The plasma thereby reduces the risk of an electrical discharge when the patterning device MA is moved away from the support structure MT. An electrostatic mirror may be used to help direct the plasma to the back side of the patterning device.

Technologies other than extraction of electrons from a miniature plasma source can provide an electron beam suitable to control patterning device potential. The electron source can be a heated wire which provides thermionic electron emission. The electron source may for example be a cold emission source (e.g. a sharp tip held in an electric field sufficiently strong to induce electron emissions from the tip). The electron source may be a DUV LED (e.g. with a wavelength in the range 200-300 nm) configured to illuminate a surface from which photo-emission takes place (i.e. a surface which has a photo-emission energy lower than the energy of the incident photons). Any of the other technologies can be assisted by a power source to form a beam of electrons of required energy, for example 10 eV . . . 100 eV.

The ionizer may for example be an inductive coil. The inductive coil may have a volume of a few mm³, e.g. less than 1 cm³. The inductive coil may have be located within the patterning device environment. Multiple inductive coils may be located within the patterning device environment.

A controller may control the ionizer such that the ionizer is switched on when the lithographic apparatus is not performing a lithographic exposure, e.g. when the patterning device MA is being unloaded from the support structure. The same may apply to the electron source.

The use of the term “electron beam” and “electron beam source” does not necessarily mean that the electrons are provided as a collimated beam. As noted further above, significant divergence of the electrons may occur.

The electron beam source may be configured such that, when the lithographic apparatus is exposing substrates, a majority of the electrons produced by the beam source and remaining in the patterning device environment may have an energy which is less than 13.6 eV.

Multiple electron beam sources may be provided.

In this document, references to ground may be interpreted as referring to electrical ground (which may alternatively be referred to as electrical earth or merely earth).

In this document, the electron beam source may be configured to direct the electron beam to a patterning device supported by the support structure. At some moments in time there may be no patterning device present on the support structure. Where this is the case, the electron beam source configuration is unchanged (although the electron beam may be switched off). This eventuality may be encompassed by referring to an area of the support structure that holds the patterning device. Thus, for example a line of sight may extend from the electron beam source to an area of the support structure that holds the patterning device. As another example, the electron beam source may be located at a distance of up to 11 cm from an area of the support structure that holds the patterning device (the thickness of the patterning device is around 1 cm).

A method according to an embodiment of the invention may be performed by a computing device. The device may comprise a central processing unit (“CPU”) to which is connected a memory. The method described herein may be implemented in code (software) stored on a memory comprising one or more storage media, and arranged for execution on a processor comprising on or more processing units. The storage media may be integrated into and/or separate from the CPU. The code, which may be referred to as instructions, is configured to be fetched from the memory and executed on the processor to perform operations in line with embodiments discussed herein. Alternatively it is not excluded that some or all of the functionality of the CPU is implemented in dedicated hardware circuitry, or configurable hardware circuitry like an FPGA.

The computing device may comprise an input configured to enable a user to input data into a software program running on the CPU. The input device may comprise a mouse, keyboard, touchscreen, microphone etc. The computing device may further comprises an output device configured to output results of measurements to a user.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Aspects of the invention are described in the following numbered clauses.

1. A lithographic patterning device contamination control system comprising a support structure configured to support a patterning device, and an electron beam source configured to emit a beam of electrons such that at least part of the beam is incident on a patterned face of a patterning device supported by the support structure during EUV exposure.
2. The lithographic patterning device contamination control system of clause 1, wherein a line of sight extends from the electron beam source to the patterning device.
3. The lithographic patterning device contamination control system of clause 2, wherein the line of sight that extends from the electron beam source to the patterning device exists for all positions of the patterning device during EUV exposure.
4. The lithographic patterning device contamination control system of any preceding clause, wherein the electron beam source is configured to emit electrons with an energy of at least 1 eV.
5. The lithographic patterning device contamination control system of any preceding clause, wherein the electron beam source is configured to emit electrons with an energy of up to 13.5 eV.
6. The lithographic patterning device contamination control system of any of clauses 1 to 4, wherein the electron beam source is configured to emit electrons with an energy of up to 100 eV.
7. The lithographic patterning device contamination control system of any of clauses 1 to 4, wherein the electron beam source is located at a distance of more than 10 cm from the patterning device and wherein the electron beam source is configured to emit electrons with an energy of at least 10 eV.
8 The lithographic patterning device contamination control system of any of clauses 1 to 6, wherein the electron beam source is located at a distance of 10 cm or less from the patterning device.
9 The lithographic patterning device of clause 8, wherein the electron beam source is located at a bottom of a housing which defines a patterning device environment, and the electron beam source is located adjacent to a wall of an opening provided in the housing.
10. The lithographic patterning device contamination control system of any preceding clause, wherein the electron beam source is configured to emit electrons with a current of at least 100 μA.
11. The lithographic patterning device contamination control system of any preceding clause, wherein the electron beam source is configured to emit electrons with a current of up to 10 mA
12. The lithographic patterning device contamination control system of any preceding clause, wherein the electron beam source is configured to output an electron beam with an elliptical cross-sectional shape.
13. The lithographic patterning device contamination control system of any of preceding clause, wherein the electron beam source plasma electrode is in contact with one of: stainless steel, tungsten, molybdenum, tantalum metals or alloys, that are resistant to sputtering by hydrogen or helium ions with energy up to 100 eV.
14. The lithographic patterning device contamination control system of any of preceding clause, wherein the electron beam source comprises at least one permanent magnet and magnetic shielding material, such as mu-metal.
15. The lithographic patterning device contamination control system of any of preceding clause, wherein the electron beam source has a housing which is grounded and is in electrical contact with a frame of the lithographic tool.
16. The lithographic patterning device contamination control system of any preceding clause, wherein the electron beam source housing is made in one of: stainless steel, tungsten, molybdenum, tantalum metals or alloys, that are resistant to sputtering by hydrogen EUV plasma.
17. The lithographic patterning device contamination control system of any preceding clause, wherein the electron beam source is connected to an RF power supply configured to provide power with a frequency in the range 0.1 GHz to 10 GHz.
18. The lithographic patterning device contamination control system of any preceding clause, wherein the electron beam source is connected to a supply of at least one of H₂ and He.
19. The lithographic patterning device contamination control system of any preceding clause, wherein the electron beam source is configured to direct the electron beam to an exposure zone within a patterning device environment.
20. The lithographic patterning device contamination control system of any of clauses 1 to 18, wherein the electron beam source is configured to direct the electron beam to a location which is offset from the exposure zone.
21. The lithographic patterning device contamination control system of clause 20, wherein an additional electron beam source is configured to direct an additional electron beam to a location which is offset in an opposite direction relative to the exposure zone.
22. The lithographic patterning device contamination control system of any of clauses 1 to 20, wherein the electron beam source is one of a plurality of electron beam sources.
23. The lithographic patterning device contamination control system of any preceding clause, wherein the electron beam source is configured to maintain the patterning device at a negative potential at least on a time-averaged basis during EUV exposure.
24. The lithographic patterning device contamination control system of any preceding clause, further comprising a controller configured to switch a polarity applied to the electron beam source such that the electron beam source outputs positive ions.
25. A lithographic apparatus comprising the patterning device contamination control system of any preceding clause, and further comprising masking blades, a patterning device exchange system, and a housing within which a patterning device environment is located.
26. The lithographic apparatus of clause 25, wherein the electron beam source is provided in a wall which defines an opening that leads to the patterning device environment.
27. The lithographic apparatus of clause 25, wherein the electron beam source is located at a height which corresponds with a height of the masking blades, and the electron beam source is offset in a direction which is orthogonal to a scanning direction of the patterning device support structure.
28. The lithographic apparatus of clause 25, wherein the electron beam source is located adjacent to a patterning device exchange system.
29. A lithographic apparatus comprising a source of electrons and an ionizer located in a patterning device environment.
30. The lithographic apparatus of clause 29, further comprising a controller configured to activate the ionizer when the lithographic apparatus is not performing a lithographic exposure.
31. A method of controlling contamination of a lithographic patterning device, the method comprising directing an electron beam to a patterned face of the patterning device.
32. The method of clause 31, wherein gas is supplied to the plasma electrode of the electron beam source, the gas comprising at least one of H₂ and He
33. The method of clause 31 or clause 32, wherein the electron beam maintains a patterned face of the patterning device at a negative potential on a time-averaged basis during EUV exposure.
34. A method of controlling charge on a back surface of a lithographic patterning device, the method comprising directing a beam of electrons or a beam of positive ions towards a back surface of the lithographic patterning device when it is manipulated by a patterning device exchange system

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1.-34. (canceled)

35. A lithographic patterning device contamination control system comprising:
a support structure configured to support a patterning device; and
an electron beam source configured to emit a beam of electrons such that at least part of the beam is incident on a patterned face of a patterning device supported by the support structure during EUV exposure.

36. The lithographic patterning device contamination control system of claim 35, wherein a line of sight extends from the electron beam source to the patterning device.

37. The lithographic patterning device contamination control system of claim 36, wherein the line of sight that extends from the electron beam source to the patterning device exists for all positions of the patterning device during EUV exposure.

38. The lithographic patterning device contamination control system of claim 35, wherein the electron beam source is configured to emit electrons with an energy of at least 1 eV.

39. The lithographic patterning device contamination control system of claim 35, wherein the electron beam source is configured to emit electrons with an energy of up to 100 eV.

40. The lithographic patterning device contamination control system of claim 35, wherein the electron beam source is located at a distance of 10 cm or less from the patterning device.

41. The lithographic patterning device contamination control system of claim 35, wherein the electron beam source is configured to emit electrons with a current of at least 100 μA.

42. The lithographic patterning device contamination control system of claim 35, wherein the electron beam source is configured to emit electrons with a current of up to 10 mA

43. The lithographic patterning device contamination control system of claim 35, wherein the electron beam source housing comprises stainless steel, tungsten, molybdenum, tantalum metals or alloys thereof, that are resistant to sputtering by hydrogen EUV plasma.

44. The lithographic patterning device contamination control system of claim 35, wherein the electron beam source is connected to a supply of at least one of H₂ and He.

45. The lithographic patterning device contamination control system of claim 35, wherein the electron beam source is configured to direct the electron beam to an exposure zone within a patterning device environment.

46. The lithographic patterning device contamination control system of claim 35, wherein the electron beam source is configured to maintain the patterning device at a negative potential at least on a time-averaged basis during EUV exposure.

47. A lithographic apparatus comprising the patterning device contamination control system of claim 35, and further comprising masking blades, a patterning device exchange system, and a housing within which a patterning device environment is located.

48. The lithographic apparatus of claim 47, wherein the electron beam source is provided in a wall that defines an opening that leads to the patterning device environment.

49. The lithographic apparatus of claim 47, wherein the electron beam source is located at a height that corresponds with a height of the masking blades, and the electron beam source is offset in a direction which is orthogonal to a scanning direction of the patterning device support structure.
